(19) United States
(12) Patent Application Publication
(10) Pub. No.: US 2014/0355336 A1
(43) Pub. Date: Dec. 4, 2014

(54) SEMICONDUCTOR MEMORY DEVICE

(71) Applicant: KABUSHIKI KAISHA TOSHIBA, Tokyo (JP)

(72) Inventor: Katsuhiko HOYA, Yokohama-shi (JP)

(21) Appl. No.: 14/018,318

(22) Filed: Sep. 4, 2013

Related U.S. Application Data
(60) Provisional application No. 61/830,852, filed on Jun. 4, 2013.

(51) Int. Cl. G11C 11/16

(52) U.S. Cl. CPC G11C 11/1675
USPC 365/158

(57) ABSTRACT

According to one embodiment, the semiconductor memory device includes a first memory cell, first, second, third and fourth interconnect lines and first, second and third write circuits. The first memory cell includes a first magnetic tunnel junction (MTJ) element. The first interconnect line is connected to one end of the first memory cell. The first write circuit drives the first interconnect line. The second interconnect line is connected to the other end of the first memory cell. The second write circuit drives the second interconnect line. The third and fourth interconnect lines are adjacent to the first memory cell. The third write circuit drives the third and fourth interconnect lines.

### CROSS-REFERENCE TO RELATED APPLICATIONS

This application claims the benefit of U.S. Provisional Application No. 61/830,852, filed Jun. 4, 2013, the entire contents of which are incorporated herein by reference.

### FIELD

Embodiments described herein relate generally to a semiconductor memory device including an MRAM.

### BACKGROUND

In a magnetic random access memory (MRAM) of an induced magnetic field type that has heretofore been developed, a memory cell passes a current through a write interconnect line disposed in the vicinity of the cell, and uses the resulting magnetic field to rewrite data. This method is not suited to scaling. A spin-transfer torque type MRAM that is mainly developed at present applies a current across both ends of a memory cell, and uses spin torque of the current. Therefore, this method requires great current drive force for cell transistor included in the memory cell. Currently, the shortage of the current drive force for the cell transistors is a major issue. This prevents writing because a current enough to write data into the memory cell cannot be applied.

### BRIEF DESCRIPTION OF THE DRAWING

FIG. 1 is a circuit diagram showing a memory cell array in an MRAM according to an embodiment;

FIGS. 2 to 8 are sectional views showing the structure of memory cells adjacent to a selected memory cell according to the embodiment;

FIG. 9 is a circuit diagram showing the structure of the MRAM according to the embodiment;

FIG. 10 is a detailed drawing of the circuit diagram shown in FIG. 9; and

FIG. 11 is a timing chart of a write operation in the MRAM according to the embodiment.

### DETAILED DESCRIPTION

Hereinafter, an MRAM as a semiconductor memory device according to an embodiment will be described with reference to the drawings. In the following explanation, components having the same functions and configurations are indicated by the same reference signs and are repeatedly described only when necessary.

In general, according to one embodiment, the semiconductor memory device includes a first memory cell, a first interconnect line, a first write circuit, a second interconnect line, a second write circuit, third and fourth interconnect lines, and a third write circuit. The first memory cell includes a first magnetic tunnel junction (MTJ) element. The first interconnect line is connected to one end of the first memory cell. The first write circuit drives the first interconnect line. The second interconnect line is connected to the other end of the first memory cell. The second write circuit drives the second interconnect line. The third and fourth interconnect lines are adjacent to the first memory cell. The third write circuit drives the third and fourth interconnect lines.

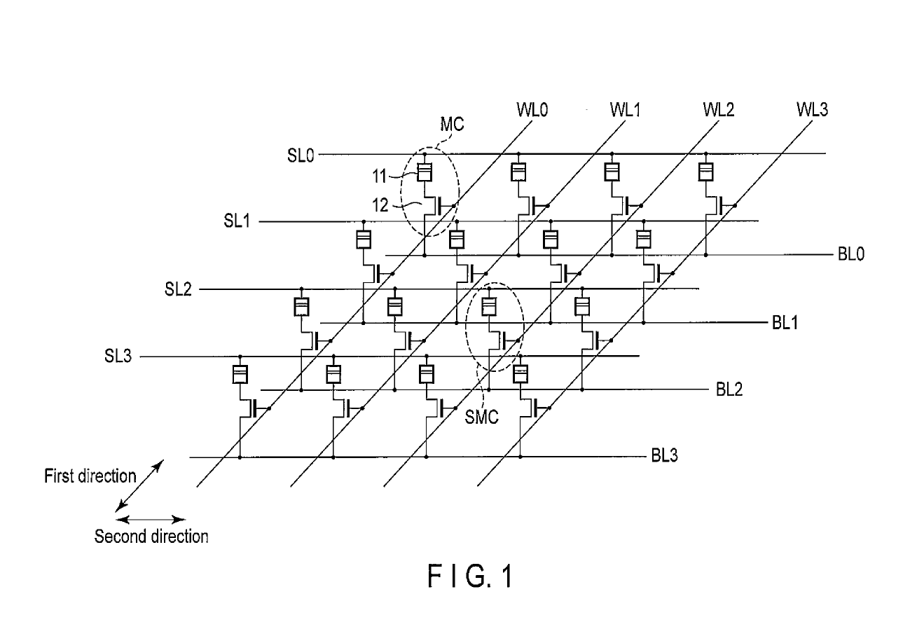

FIG. 1 is a circuit diagram showing a memory cell array in the MRAM according to the embodiment.

As shown, word lines WL0 to WL3 extending in a first direction (word line direction) are arranged in a second direction (bit line direction). Bit lines BL0 to BL3 extending in the second direction are arranged in the first direction. Moreover, source lines SL0 to SL3 extending in the second direction are arranged in the first direction.

A memory cell MC is disposed at the intersection of the bit line, the source line and the word line. The memory cell MC includes a magnetic tunnel junction (MTJ) element 11 and a select transistor 12 which are connected in series between the bit line and the source line. The bit line is connected to one end of the memory cell MC. The source line is connected to the other end of the memory cell MC. The word line is connected to the gate of the select transistor 12.

In the present embodiment, when, for example, the word line WL2 is selected and data is written from the bit line BL2 and the source line SL2 during a write operation, a current is passed through the source lines SL1 and SL3 adjacent to the source line SL2 of a selected memory cell SMC. As a result, a magnetic field is generated toward the memory cell SMC, and the MTJ element 11 is changed to an energy state that easily causes spin reversal. This allows a small write current to cause writing into the memory cell SMC by spin-transfer torque, that is, the inversion of the spin direction (magnetization direction) of a storage layer (or free layer) in the MTJ element.

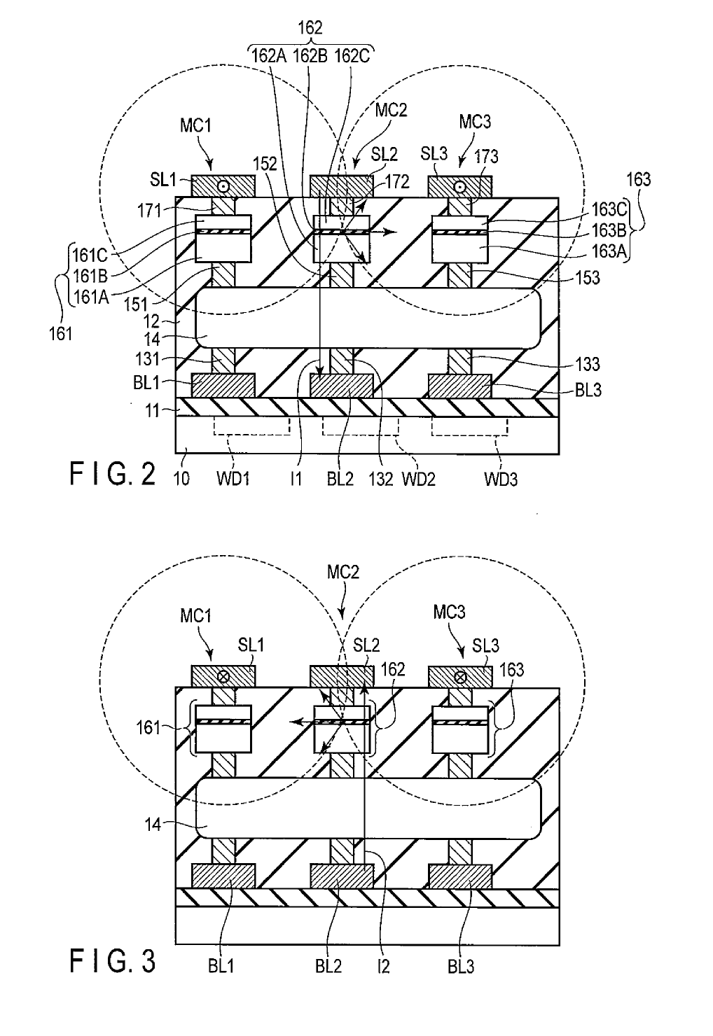

FIGS. 2 to 8 are sectional views showing the structure of memory cells adjacent to a selected cell according to the embodiment.

First, the sectional structure of the memory cell is described with reference to FIG. 2. Here, the selected memory cell is indicated by MC2, and the memory cells adjacent to the selected memory cell MC2 are indicated by MC1 and MC3.

An interlayer insulating film 11 is formed on a semiconductor substrate 10, and the bit lines BL1, BL2, and BL3 are formed on the interlayer insulating film 11. An interlayer insulating film 12 is formed on the bit lines BL1, BL2, and BL3.

A contact plug 131, a select transistor 14, a contact plug 151, an MTJ element 161, and a contact plug 171 are formed in order on the bit line BL1 in the interlayer insulating film 12. Moreover, the source line SL1 is formed on the contact plug 171 and on the interlayer insulating film 12.

A contact plug 132, the select transistor 14, a contact plug 152, an MTJ element 162, and a contact plug 172 are formed in order on the bit line BL2 in the interlayer insulating film 12. Moreover, the source line SL2 is formed on the contact plug 172 and on the interlayer insulating film 12.

A contact plug 133, the select transistor 14, a contact plug 153, an MTJ element 163, and a contact plug 173 are formed in order on the bit line BL3 in the interlayer insulating film 12. Moreover, the source line SL3 is formed on the contact plug 173 and on the interlayer insulating film 12.

Although the select transistors 14 are respectively connected to the MTJ elements 161, 162, and 163, the select transistors 14 are shown as one region where these select transistors are formed.

That is, the memory cell MC1 includes the MTJ element 161 and the select transistor 14. The MTJ element 161 has a stack structure of a fixed layer (or reference layer) 161A, an insulation layer (tunnel barrier layer) 161B, and a storage layer 161C. The fixed layer 161A maintains a predetermined magnetization direction. The storage layer 161C faces the fixed layer 161A, and is variable in magnetization direction. The insulation layer 161B is disposed between the fixed layer 161A and the storage layer 161C.

The fixed layer 161A is connected to the select transistor 14. The select transistor 14 is formed by a transistor such as a surround gate transistor (SGT) or a fin transistor having a three-dimensional structure. The surround gate transistor comprises, for example, a MOS transistor formed into columnar polysilicon deposited on the semiconductor substrate. This transistor has a surround gate structure in which a source and a drain are disposed at the top and bottom of the column and in which a gate is disposed around the side surface of the column. The fin transistor is a Si layer formed by fabricating the part between a source and a drain into a thin fin shape which is covered with an insulating film and a gate in the shape of C.

Furthermore, the select transistor 14 is connected to the bit line BL1. The storage layer 161C of the MTJ element 161 is connected to the source line SL1.

The memory cell MC2 includes the MTJ element 162 and the select transistor 14. The MTJ element 162 has a stack structure of a fixed layer (or reference layer) 162A, an insulation layer (tunnel barrier layer) 162B, and a storage layer 162C. The fixed layer 162A maintains a predetermined magnetization direction. The storage layer 162C faces the fixed layer 162A, and is variable in magnetization direction. The insulation layer 162B is disposed between the fixed layer 162A and the storage layer 162C.

The fixed layer 162A is connected to the select transistor 14. The select transistor 14 is connected to the bit line BL2. The storage layer 162C of the MTJ element 162 is connected to the source line SL2.

The memory cell MC3 includes the MTJ element 163 and the select transistor 14. The MTJ element 163 has a stack structure of a fixed layer (or reference layer) 163A, an insulation layer (tunnel barrier layer) 163B, and a storage layer 163C. The fixed layer 163A maintains a predetermined magnetization direction. The storage layer 163C faces the fixed layer 163A, and is variable in magnetization direction. The insulation layer 163B is disposed between the fixed layer 163A and the storage layer 163C.

The fixed layer 163A is connected to the select transistor 14. The select transistor 14 is connected to the bit line BL3. The storage layer 163C of the MTJ element 163 is connected to the source line SL3.

Now, the direction of a current and the direction of a magnetic field during a write operation are described with reference to FIGS. 2 to 8. How the magnetic field applied to the selected memory cell MC2 varies with the direction of the current passed through the source lines (or bit lines) SL1 and SL3 adjacent to the selected memory cell MC2 is shown in FIGS. 2 to 8.

In the writing shown in FIG. 2, a current I1 runs from the source line SL2 to the bit line BL2. In this case, a current is passed through the source lines SL1 and SL3 adjacent to the source line SL2 from the far side to the near side of the drawing as shown in FIG. 2. As a result, the magnetic field applied to the MTJ element 162 of the selected memory cell MC2 becomes horizontal (the MTJ element 162→163). The horizontal direction is the hard-axis direction of the memory cell MC2, and the spin energy state is high so that the application of a magnetic field in a horizontal direction facilitates spin reversal with a small write current. That is, writing can be performed with a small write current.

At the same time, a horizontal magnetic field is also applied to the memory cells MC1 and MC3 immediately under the source lines SL1 and SL3 through which a current is passed. However, no write current runs through the unselected memory cells MC1 and MC3. Therefore, as far as the magnetic field in the hard-axis direction alone is concerned, it is possible to produce a condition in which no writing is performed in the unselected memory cells MC1 and MC3.

In the writing shown in FIG. 3, a current I2 runs from the bit line BL2 to the source line SL2. In this case, a current is passed through the source lines SL1 and SL3 adjacent to the source line SL2 from the near side to the far side of the drawing as shown in FIG. 3. As a result, the magnetic field applied to the MTJ element 162 of the selected memory cell MC2 becomes horizontal (the MTJ element 162→161). The horizontal direction is the hard-axis direction of the memory cell MC2, and the spin energy state is high so that the application of a magnetic field in a horizontal direction facilitates spin reversal with a small write current. That is, writing can be performed with a small write current.

At the same time, a horizontal magnetic field is also applied to the memory cells MC1 and MC3 immediately under the source lines SL1 and SL3 through which a current is passed. However, no write current runs through the unselected memory cells MC1 and MC3. Therefore, as far as the magnetic field in the hard-axis direction alone is concerned, it is possible to produce a condition in which no writing is performed in the unselected memory cells MC1 and MC3.

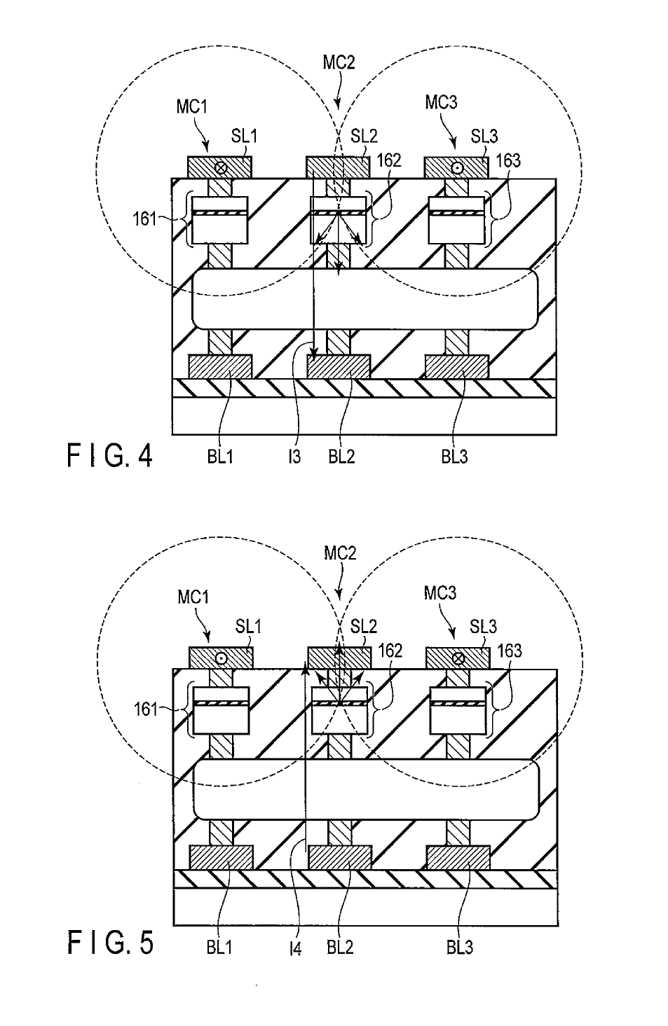

In the writing shown in FIG. 4, a current I3 runs from the source line SL2 to the bit line BL2. In this case, a current is passed through the source line SL1 adjacent to the source line SL2 from the near side to the far side of the drawing as shown in FIG. 4. In parallel, a current is passed through the source line SL3 adjacent to the source line SL2 from the far side to the near side of the drawing as shown in FIG. 4. As a result, the magnetic field applied to the MTJ element 162 of the selected memory cell MC2 becomes vertical (the MTJ element 162→BL2). Thus, the storage layer 162C of the MTJ element 162 is changed to an energy state that easily causes spin reversal. This facilitates spin reversal with a small write current. That is, writing can be performed with a small write current.

At the same time, a vertical magnetic field is also applied to the memory cells MC1 and MC3 immediately under the source lines SL1 and SL3 through which a current is passed. However, no write current runs through the unselected memory cells MC1 and MC3. Therefore, as far as the magnetic field in the vertical direction alone is concerned, it is possible to produce a condition in which no writing is performed in the unselected memory cells MC1 and MC3.

In the writing shown in FIG. 5, a current I4 runs from the bit line BL2 to the source line SL2. In this case, a current is passed through the source line SL1 adjacent to the source line SL2 from the far side to the near side of the drawing as shown in FIG. 5. In parallel, a current is passed through the source line SL3 adjacent to the source line SL2 from the near side to the far side of the drawing as shown in FIG. 5. As a result, the magnetic field applied to the MTJ element 162 of the selected memory cell MC2 becomes vertical (the MTJ element 162→SL2). Thus, the storage layer 162C of the MTJ element 162 is changed to an energy state that easily causes spin reversal. This facilitates spin reversal with a small write current. That is, writing can be performed with a small write current.

At the same time, a vertical magnetic field is also applied to the memory cells MC1 and MC3 immediately under the source lines SL1 and SL3 through which a current is passed. However, no write current runs through the unselected memory cells MC1 and MC3. Therefore, as far as the magnetic field in the vertical direction alone is concerned, it is possible to produce a condition in which no writing is performed in the unselected memory cells MC1 and MC3.

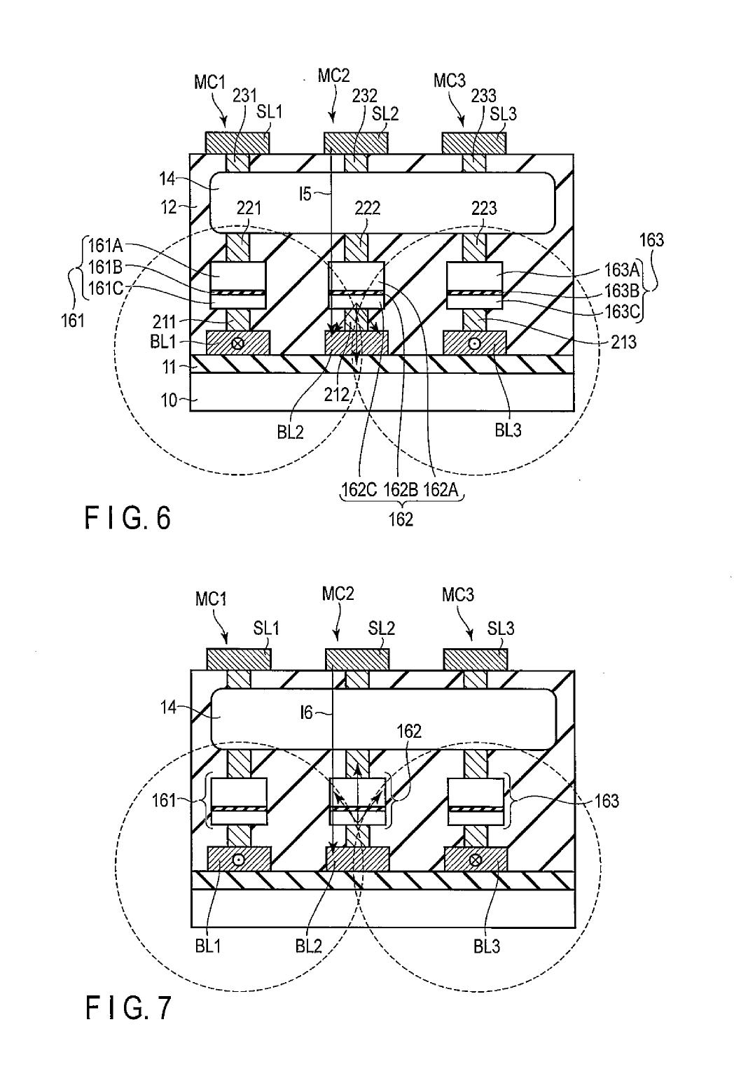

The sectional structure of another example of a memory cell shown in FIGS. 6 and 7 is described. In the memory cell shown in FIGS. 6 and 7 which is different in sectional structure from the memory cell shown in FIG. 2, an MTJ element is disposed on the bit line on the semiconductor substrate side, and a select transistor is disposed on the source line side. Here, the selected memory cell is indicated by MC2, and the memory cells adjacent to the selected memory cell MC2 are indicated by MC1 and MC3.

A contact plug 211, an MTJ element 161, a contact plug 221, a select transistor 14, and a contact plug 231 are formed in order on the bit line BL1 in the interlayer insulating film 12. Moreover, the source line SL1 is formed on the contact plug 231 and on the interlayer insulating film 12.

A contact plug 212, an MTJ element 162, a contact plug 222, the select transistor 14, and a contact plug 232 are formed in order on the bit line BL2 in the interlayer insulating film 12. Moreover, the source line SL2 is formed on the contact plug 232 and on the interlayer insulating film 12.

A contact plug 213, an MTJ element 163, a contact plug 223, the select transistor 14, and a contact plug 233 are formed in order on the bit line BL3 in the interlayer insulating film 12. Moreover, the source line SL3 is formed on the contact plug 233 and on the interlayer insulating film 12. In other respects, the configuration is similar to that shown in FIG. 2.

In the writing shown in FIG. 6, a current I5 runs from the source line SL2 to the bit line BL2. In this case, a current is passed through the bit line BL1 adjacent to the bit line BL2 from the near side to the far side of the drawing as shown in FIG. 6. In parallel, a current is passed through the bit line BL3 adjacent to the bit line BL2 from the far side to the near side of the drawing as shown in FIG. 6. As a result, the magnetic field applied to the MTJ element 162 of the selected memory cell MC2 becomes vertical (the MTJ element 162→BL2). Thus, the storage layer 162C of the MTJ element 162 is changed to an energy state that easily causes spin reversal. This facilitates spin reversal with a small write current. That is, writing can be performed with a small write current.

At the same time, a vertical magnetic field is applied to the memory cells MC1 and MC3 immediately above the bit lines BL1 and BL3 through which a current is passed. However, no write current runs through the unselected memory cells MC1 and MC3. Therefore, as far as the magnetic field in the vertical direction alone is concerned, it is possible to produce a condition in which no writing is performed in the unselected memory cells MC1 and MC3.

In the writing shown in FIG. 7, a current I6 runs from the source line SL2 to the bit line BL2. In this case, a current is passed through the bit line BL1 adjacent to the bit line BL2 from the far side to the near side of the drawing as shown in FIG. 7. In parallel, a current is passed through the bit line BL3 adjacent to the bit line BL2 from the near side to the far side of the drawing as shown in FIG. 7. As a result, the magnetic field applied to the MTJ element 162 of the selected memory cell MC2 becomes vertical (the MTJ element 162→SL2). Thus, the storage layer 162C of the MTJ element 162 is changed to an energy state that easily causes spin reversal. This facilitates spin reversal with a small write current. That is, writing can be performed with a small write current.

At the same time, a vertical magnetic field is applied to the memory cells MC1 and MC3 immediately above the bit lines BL1 and BL3 through which a current is passed. However, no write current runs through the unselected memory cells MC1 and MC3. Therefore, as far as the magnetic field in the vertical direction alone is concerned, it is possible to produce a condition in which no writing is performed in the unselected memory cells MC1 and MC3.

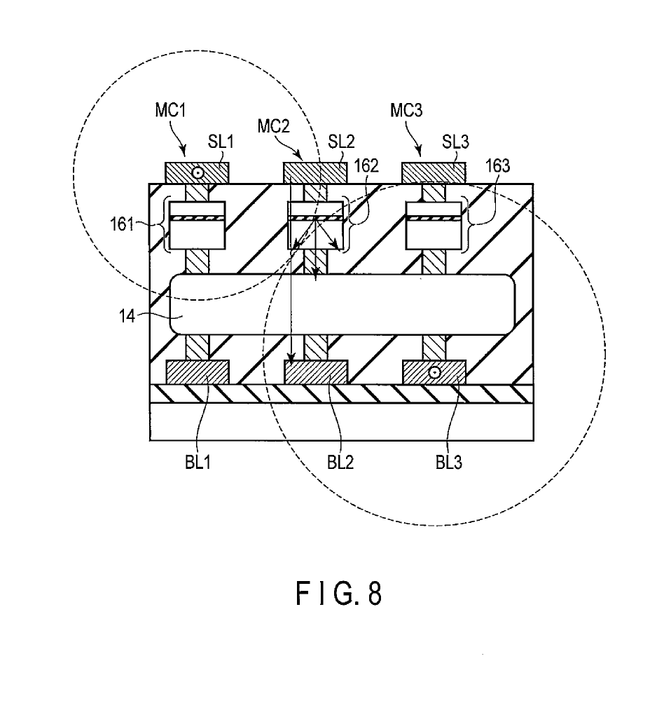

The memory cell shown in FIG. 8 is similar to the memory cell shown in FIG. 2. In the writing shown in FIG. 8, a current is passed through the source line SL1 and the bit line BL3 that are located diagonally to the selected memory cell MC2, and a magnetic field can thereby be applied to the MTJ element 162 of the selected memory cell MC2. A current may be passed through the source line SL3 and the bit line BL1. A magnetic field can also be applied to the selected memory cell MC2 if a current is passed through one of the source and bit lines adjacent to the selected memory cell MC2. For example, a current is passed through the source line SL1 and the bit line BL3 from the far side to the near side of the drawing as shown in FIG. 8. As a result, the magnetic field applied to the MTJ element 162 of the selected memory cell MC2 becomes vertical (the MTJ element 162→BL2). Thus, the storage layer 162C of the MTJ element 162 is changed to an energy state that easily causes spin reversal. This facilitates spin reversal with a small write current. That is, writing can be performed with a small write current.

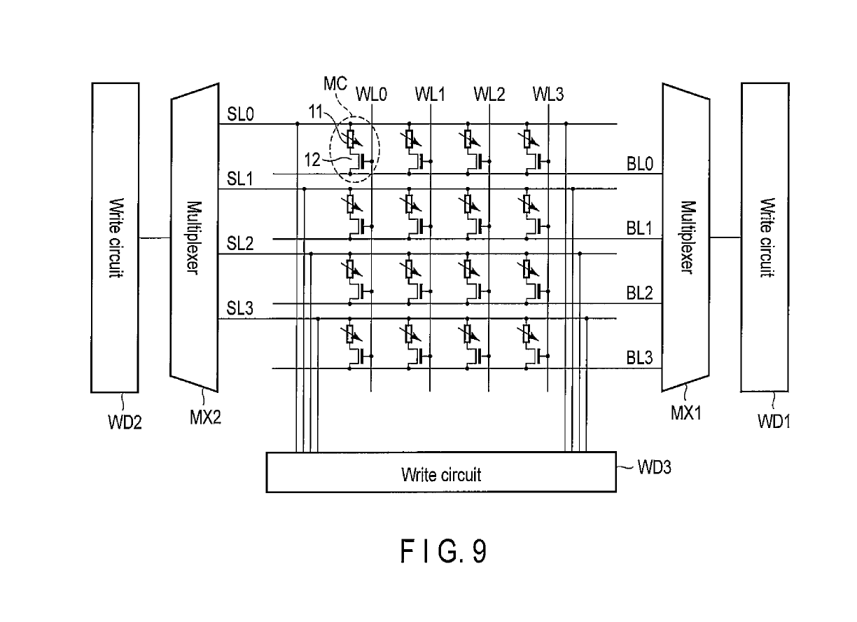

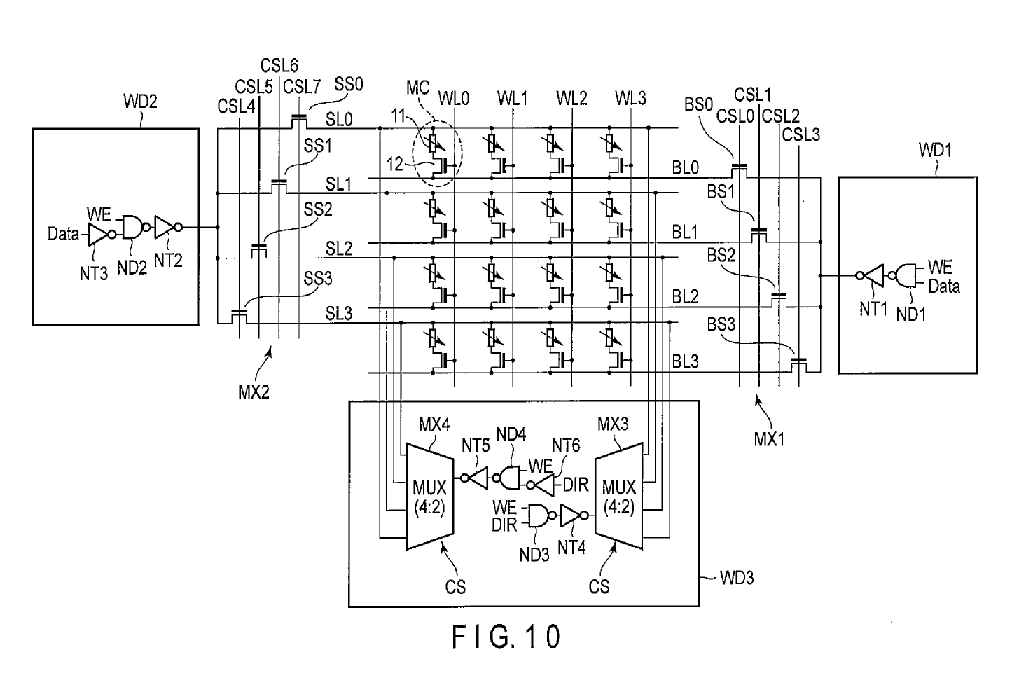

FIG. 9 is a circuit diagram showing the configuration of the MRAM according to the embodiment. FIG. 10 is a more detailed drawing of the circuit diagram shown in FIG. 9.

As shown in FIG. 9, the configuration of a memory cell array is similar to that shown in FIG. 1, and is therefore not described. A multiplexer MX1 is connected to the bit lines BL0 to BL3, and a write circuit WD1 is connected to the multiplexer MX1. A multiplexer MX2 is connected to the source lines SL0 to SL3, and a write circuit WD2 is connected to the multiplexer MX2. A write circuit WD3 is connected to each of the source lines SL0 to SL3. The write circuit WD3 can bi-directionally pass a current through each of the source lines SL0 to SL3.

As shown in FIG. 2, the write circuits WD1, WD2, and WD3 are formed in the semiconductor substrate 10 under the memory cell array. That is, the write circuits WD1, WD2, and WD3 can be disposed in the semiconductor substrate 10 under the region where the MTJ elements 161, 162, and 163 and the select transistor 14 are formed. Therefore, even the configuration to which the write circuit WD3 is added as in the present embodiment does not lead to a considerable increase in area.

Now, the multiplexer and the write circuit in FIG. 9 are described in detail.

As shown in FIG. 10, the multiplexer MX1 has switching transistors BS0 to BS3, and column selection lines CSL0 to CSL3 are connected to the gates of the switching transistors BS0 to BS3, respectively. A NOT circuit NT1 and a NAND circuit ND1 are connected to the bit lines BL0 to BL3 via the switching transistors BS0 to BS3. Write data and a write enable signal WE are input to first and second input terminals of the NAND circuit ND1, respectively.

The multiplexer MX2 has switching transistors SS0 to SS3, and column selection lines CSL4 to CSL7 are connected to the gates of the switching transistors SS0 to SS3, respectively. A NOT circuit NT2, a NAND circuit ND2, and a NOT circuit NT3 are connected to the source lines SL0 to SL3 via the switching transistors SS0 to SS3. Write data is input to an input terminal of the NOT circuit NT3, and a write enable signal WE is input to a first input terminal of the NAND circuit ND2.

The write circuit WD3 has multiplexers MX3 and MX4, NOT circuits NT4 to NT6, and NAND circuits ND3 and ND4. The multiplexer MX3 is connected to one end of each of the source lines SL0 to SL3, and the NOT circuit NT4 and the NAND circuit ND3 are connected to the multiplexer MX3. A direction signal that indicates the direction of a current to be passed through the source lines is supplied to a first input terminal of the NAND circuit ND3. A write enable signal WE is input to a second input terminal of the NAND circuit ND3. A column selection signal CS is input to the multiplexer MX3. The multiplexer MX3 selects two source lines adjacent to the selected memory cell in accordance with the column selection signal CS.

The multiplexer MX4 is connected to the other end of the each of the source lines SL0 to SL3, and the NOT circuit NT5, the NAND circuit ND4, and the NOT circuit NT6 are connected to the multiplexer MX4 in order. A direction signal that indicates the direction of a current to be passed through the source line is supplied to an input terminal of the NOT circuit NT6. An output terminal of the NOT circuit NT6 is connected to a first input terminal of the NAND circuit ND4. A write enable signal WE is input to a second input terminal of the NAND circuit ND4. A column selection signal CS is input to the multiplexer MX4. The multiplexer MX4 selects two source lines adjacent to the selected memory cell in accordance with the column selection signal CS.

Now, a write operation in the MRAM according to the embodiment is described.

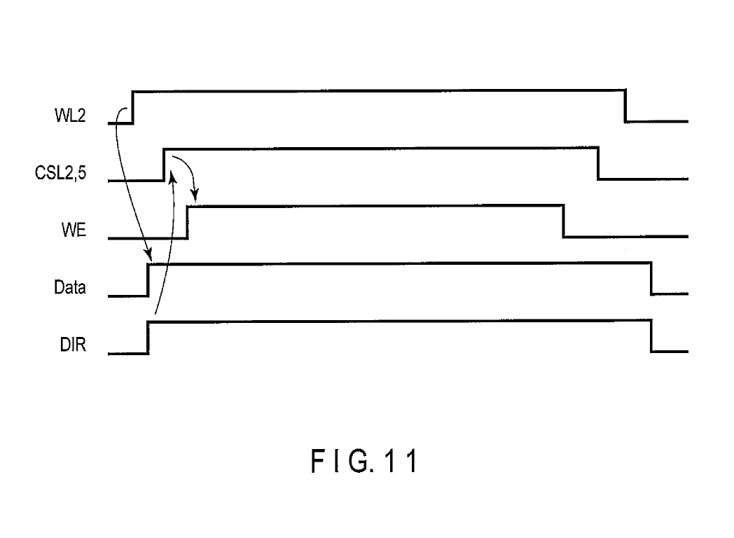

A timing chart of the write operation is shown in FIG. 11. Here, writing is performed in a memory cell selected by the word line WL2, the bit line BL2, and the source line SL2.

First, the word line WL2 is activated. Write data is then input to the write circuits WD1 and WD2. Further, the source lines SL1 and SL3 adjacent to the selected memory cell are selected. A signal DIR for setting the direction of a current to be passed through the source lines SL1 and SL3 is then input. Further, a signal is input to the column selection lines CSL2 and CSL5, and a memory cell to write into is selected. The write enable signal WE is then input to start writing.

That is, during writing, the word line WL2 is selected, and the write data and the direction of a current to be passed through the source lines SL1 and SL3 adjacent to the selected source line are specified. Further, the column selection signal CS is input, and an adjacent source line is selected. Finally, the write enable signal WE is input to enable writing.

As described above, according to the embodiment, a current is applied to the neighboring source lines SL with no addition of interconnect lines to a memory cell array including cell transistors such as the SGT, a bipolar diode, and a MOS transistor through which a current necessary for writing cannot be passed, in the MRAM that uses a magnetic tunnel junction (MTJ) element as a memory element. This assists in writing into the memory cell. Consequently, it is possible to accomplish a writing operation even in a miniaturized MRAM.

In the embodiment described above, the select transistor 14 may be located on the semiconductor substrate 10, and both the bit lines BL and the source lines SL may be located higher than the select transistor 14. More specifically, in a memory cell having a cell structure other than a cell structure in which one memory cell comprises 4F², the select transistor 14 may be located on the semiconductor substrate 10, and both the bit lines BL and the source lines SL may be located above the select transistor 14. F represents a minimum feature size.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first memory cell including a first magnetic tunnel junction (MTJ) element;
a first interconnect line connected to one end of the first memory cell;
a first write circuit which drives the first interconnect line;
a second interconnect line connected to the other end of the first memory cell;
a second write circuit which drives the second interconnect line;
third and fourth interconnect lines adjacent to the first memory cell; and
a third write circuit which drives the third and fourth interconnect lines.

2. The semiconductor memory device according to claim 1, wherein
the third write circuit passes a current through the third and fourth interconnect lines during writing into the first memory cell.

3. The semiconductor memory device according to claim 1, wherein
the third write circuit is formed in a semiconductor substrate under the first memory cell.

4. The semiconductor memory device according to claim 1, further comprising:
a second memory cell which includes a second magnetic tunnel junction (MTJ) element and which is disposed adjacent to the first memory cell; and
a third memory cell which includes a third magnetic tunnel junction (MTJ) element and which is disposed adjacent to the first memory cell,
wherein the first, second, and third memory cells are disposed on a semiconductor substrate,
the first interconnect line is disposed on the first memory cell,
the third interconnect line is disposed on the second memory cell and connected to one end of the second memory cell, and
the fourth interconnect line is disposed on the third memory cell and connected to one end of the third memory cell.

5. The semiconductor memory device according to claim 4, wherein
the first memory cell comprises a first select transistor connected to the first MTJ element,
the second memory cell comprises a second select transistor connected to the second MTJ element,
the third memory cell comprises a third select transistor connected to the third MTJ element, and
the first, second, and third select transistors are disposed on the semiconductor substrate, and the first, second, and third MTJ elements are disposed on the first, second, and third select transistors.

6. The semiconductor memory device according to claim 5, wherein
the first, second, and third select transistors include one of surround gate transistors and fin transistors.

7. The semiconductor memory device according to claim 4, wherein
the third write circuit passes a current through the third and fourth interconnect lines during writing into the first memory cell.

8. The semiconductor memory device according to claim 4, wherein
the third write circuit passes currents in the same direction through the third and fourth interconnect lines during writing into the first memory cell.

9. The semiconductor memory device according to claim 4, wherein
the third write circuit passes currents in opposite directions through the third and fourth interconnect lines during writing into the first memory cell.

10. The semiconductor memory device according to claim 2, wherein
the third write circuit controls the direction of a current to be passed through the third and fourth interconnect lines in accordance with a selection signal.

11. The semiconductor memory device according to claim 4, further comprising:
a fifth interconnect line which is disposed between the third memory cell and the semiconductor substrate and which is connected to the other end of the third memory cell,
wherein the third write circuit passes currents in the same direction through the third and fifth interconnect lines during writing into the first memory cell.

12. The semiconductor memory device according to claim 1, further comprising:
a second memory cell which includes a second magnetic tunnel junction (MTJ) element and which is disposed adjacent to the first memory cell; and
a third memory cell which includes a third magnetic tunnel junction (MTJ) element and which is disposed adjacent to the first memory cell,
wherein the first, second, and third memory cells are disposed on a semiconductor substrate,
the first interconnect line is disposed between the semiconductor substrate and the first memory cell,
the third interconnect line is disposed between the semiconductor substrate and the second memory cell and connected to one end of the second memory cell, and
the fourth interconnect line is disposed between the semiconductor substrate and the third memory cell and connected to one end of the third memory cell.

13. The semiconductor memory device according to claim 12, wherein
the first memory cell comprises a first select transistor connected to the first MTJ element,
the second memory cell comprises a second select transistor connected to the second MTJ element,
the third memory cell comprises a third select transistor connected to the third MTJ element, and
the first, second, and third MTJ elements are disposed on the semiconductor substrate, and the first, second, and third select transistors are disposed on the first, second, and third MTJ elements.

14. The semiconductor memory device according to claim 13, wherein
the first, second, and third select transistors include one of surround gate transistors and fin transistors.

15. The semiconductor memory device according to claim 12, wherein
the third write circuit passes a current through the third and fourth interconnect lines during writing into the first memory cell.

16. The semiconductor memory device according to claim 12, wherein
the third write circuit passes currents in the same direction through the third and fourth interconnect lines during writing into the first memory cell.

17. The semiconductor memory device according to claim 12, wherein
the third write circuit passes currents in opposite directions through the third and fourth interconnect lines during writing into the first memory cell.

18. A method of writing in a semiconductor memory device, the method comprising:
passing a write current across one end and the other of a memory cell including a magnetic tunnel junction (MTJ) element during writing, by a write circuit;
selecting an interconnect line adjacent to the memory cell in accordance with a selection signal during the writing, by a write circuit; and
passing a current through the selected interconnect line during the writing, by a write circuit.

19. The writing method according to claim 18, wherein
receiving a direction signal that indicates the direction of a current, and setting the direction of the current to be passed through the interconnect line in accordance with the direction signal, by a write circuit.

20. The writing method according to claim 18, wherein
selecting a plurality of interconnect lines adjacent to the memory cell, and passing currents in the same direction through the selected interconnect lines, by a write circuit.
